(19) United States
(12) Patent Application Publication
(10) Pub. No.: US 2026/0188568 A1
(43) Pub. Date: Jul. 2, 2026

(54) MAGNETIC FLUX CANCELLATION INDUCTOR PAIRING

(71) Applicant: NVIDIA CORPORATION, Santa Clara, CA (US)

(72) Inventors: Gabriele GORLA, Santa Clara, CA (US); Charlie J. SHU, San Ramon, CA (US); Chen WANG, Santa Clara, CA (US); Lizhi ZENG, Shenzhen, Guangdong (CN); Charles JACKSON, Austin, TX (US)

(21) Appl. No.: 18/697,922

(22) PCT Filed: Feb. 28, 2024
(86) PCT No.: PCT/CN2024/079107

§ 371 Date: Apr. 2, 2024

(51) Int. Cl. H01F 27/34; H01F 27/28; H05K 1/181

(52) U.S. Cl. CPC H01F 27/34; H01F 27/28; H05K 1/181; H05K 2201/1003

(57) ABSTRACT

In various embodiments, an inductor package comprises a first inductor that is arranged in a first orientation and produces a first magnetic flux in a first direction; and a second inductor that is arranged in a second orientation and produces a second magnetic flux in a second direction that at least partially cancels the first magnetic flux, where the first direction is opposite the second direction. In some embodiments, a printed circuit board assembly comprises a printed circuit board (PCB) layer, a first inductor that is arranged on the PCB layer at a first orientation and produces a first magnetic flux in a first direction, and a second inductor that is arranged on the PCB layer at a second orientation and produces a second magnetic flux in a second direction that at least partially cancels the first magnetic flux.

### BACKGROUND

### Field of the Various Embodiments

The various embodiments relate generally to computer systems and electrical circuits and, more specifically, to a magnetic flux cancellation inductor pairing.

### Description of the Related Art

Computer devices typically include various electronic circuits to regulate the power delivered to components within those devices and systems during operation. For example, many computing devices include multiple power control circuits. Computing devices typically also include electronic circuits that have differing combinations of resistors (R), inductors (L), and capacitors (“RLC circuits”) for various applications and operations, such as controlling oscillations, filtering, and tuning, to name a few. When designing electronic circuits, designers attempt to minimize parasitic characteristics associated with components making up the electronic circuits, such as the inductors included in a RLC circuit. However, high-performance computer devices, such as laptops, desktops, motherboards having high-performance integrated circuits and other high-performance components, and graphical processing units (GPUs), consume large amounts of power and therefore require large inductors with high current ratings to control the power drawn by those devices during operation. Consequently, designers oftentimes select power inductors with high-current ratings for use in high-performance computer devices.

However, one characteristic of power inductors with high-current ratings is that using these type of power inductors can create substantial magnetic flux leakage that can cause electromagnetic interference (EMI) problems with respect to the other electronic components within a computer device or system. For example, conducted emission failures can result from the electromagnetic interference caused by magnetic flux spreading to various electronic components within a computer device via connected power lines or communication lines. These types of failures can prevent the computer device from satisfying electromagnetic compatibility regulatory requirements.

To mitigate electromagnetic interference caused by magnetic flux leakage, designers sometimes try to ensure that there are adequate distances between the inductors and the other electronic components within a computer device oftentimes add additional materials to the other electronic components, such as absorbent material or metal covers, to block the effects of any magnetic flux leakage that may occur during operation. These preventative measures, however, can increase form factors when using inductors made with low magnetic permeability materials. Accordingly, in other approaches, designers attempt to address magnetic flux leakage issues by adding other structures, such as heatsinks to the circuit, as well as EMI clips to connect the heatsinks to the inductors. These types of additional structures can act to reduce the amount of magnetic flux emanating from the inductor packages in a computer device. However, one drawback of using additional structures is that conventional heatsinks and EMI clips oftentimes are not terribly effective, given that heatsinks can also create electromagnetic interference that can inhibit the operation of other components with the computer device. Further, adding additional components increases the footprint size of the inductors within a computer device, which reduces the number of inductors that can be included in a given computer device.

As the foregoing illustrates, what is needed in the art are more effective designs for the inductors implemented in high-performance computer devices.

### SUMMARY

In various embodiments, an inductor package comprises a first inductor that is arranged in a first orientation and produces a first magnetic flux in a first direction; and a second inductor that is arranged in a second orientation and produces a second magnetic flux in a second direction that at least partially cancels the first magnetic flux, where the first direction is opposite the second direction.

In various embodiments, a printed circuit board assembly comprises a printed circuit board (PCB) layer, a first inductor that is arranged on the PCB layer at a first orientation and produces a first magnetic flux in a first direction, and a second inductor that is arranged on the PCB layer at a second orientation and produces a second magnetic flux in a second direction that at least partially cancels the first magnetic flux.

At least one technical advantage of the disclosed design relative to the prior art is that, with the disclosed design, a printed circuit board assembly or inductor package includes a complementary pair of inductors that are arranged to limit the magnetic flux that leaks from inductors. In particular, by physically arranging inductors in orientations that produce magnetic fluxes in opposing directions, circuits that use the complementary pair of inductors can drive each inductor in a given inductor pair with large currents without causing a large magnetic flux. Consequently, the disclosed design enables a greater density of inductors to be included in a computer device, such as a printed circuit board, relative to what can be achieved using prior art designs. Further, with the disclosed design, pairs of inductors and inductor packages can be located closer to the other components in a computer device relative to what can be achieved using prior art designs. Accordingly, the disclosed design can improve the ability of a high-performance computing devices to control power use during operation. These technical advantages represent one or more technological improvements over prior art approaches and designs.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a switched mode power supply circuit that includes an exemplar inductor pair, according to various embodiments.

FIG. 2 illustrates an exemplar pair of cylindrical coil inductors arranged to produce cancelling magnetic fields, according to various embodiments.

FIG. 3 illustrates an exemplar pair of bridge configuration inductors arranged to produce cancelling magnetic fields, according to various embodiments.

FIG. 4 illustrates an exemplar pair of cylindrical coil inductors arranged in parallel to produce cancelling magnetic fields, according to various embodiments.

FIG. 5 illustrates a printed circuit board (PCB) assembly that includes one or more inductor packages and one or more 2-in-1 inductor packages, according to various embodiments.

FIG. 6 is a block diagram of a computer system configured to implement one or more aspects of the various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

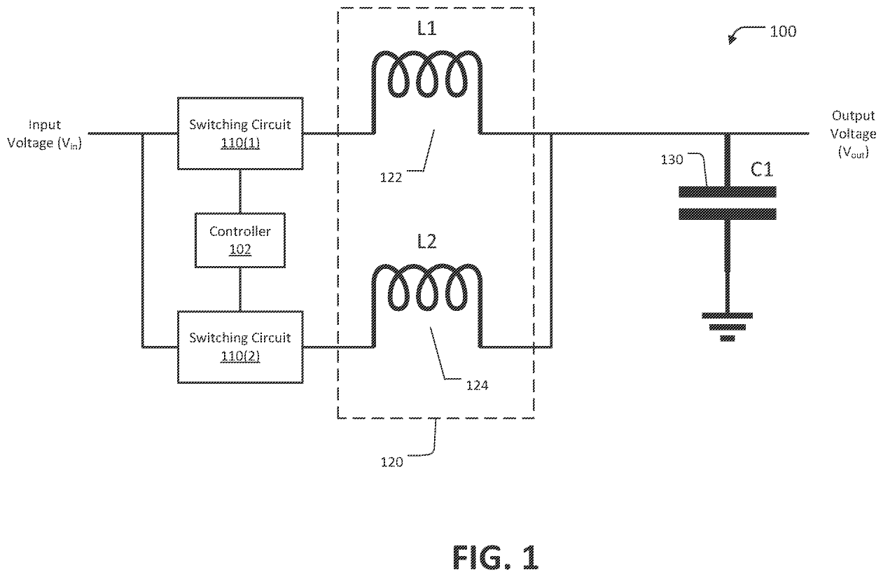

FIG. 1 illustrates a switched mode power supply circuit 100 that includes an exemplar inductor pair 120, according to various embodiments. As shown, the switched mode power supply circuit 100 includes, without limitation, a controller 102, switching circuits 110, an inductor pair 120, and a capacitor 130. The inductor pair 120 includes, without limitation, a first inductor (L1) 122 and a second inductor (L2) 124.

The switched mode power supply (SMPS) circuit 100 is configured to receive an input voltage Vᵢₙ and provide an output voltage Vₒᵤₜ to a load. In various embodiments, SMPS circuit 100 includes a controller 102 that controls one or more switching circuits 110 (e.g., 110(1), 110(2) to control when the respective inductor 122, 124 is connected to the input voltage. For example, the topology of the inductors in relation to the capacitor 130 and a resistor (not shown) can be modified such that the SMPS circuit 100 is a buck converter, a boost converter, a buck-boost, converter, and so forth. The SMPS circuit 100 can be used to provide a consistent output voltage to a connected load.

In some examples, the load is an electronic component, such as a processor, a memory, a semiconductor, such as a central processing unit (CPU), a graphics processing unit (GPU), a high-current application-specific integrated circuit (ASIC), and/or a field programmable gate array (FPGA), incorporated in a computer device or system. As persons skilled in the art will appreciate, a computing device or system that includes the load powered by the SMPS circuit 100 can be any type of technically feasible computer system, including, without limitation, a server machine, a server platform, a desktop machine, a laptop machine, a hand-held/mobile device, or a wearable device. Furthermore, persons skilled in the art will understand that the SMPS circuit 100 can also be used to power other types of components.

The switching circuits 110 include a plurality of switches that control a current that is provided to the respective inductors 122, 124. In some embodiments, the switches can include one or more transistors, such as n-type or p-type metal-oxide-semiconductor field-effect transistor (MOSFETs) that open or close based on the PWM signal to enable a current to flow to the connected inductor 122, 124. In some embodiments, one or more of the switching circuits 110(1), 110(23) can be driver and MOSFET combination (DrMOS) that includes power drivers for the plurality of MOSFETs included in a given switching circuit 110.

In various embodiments, the switching circuits 110(1), 110(2) generate a phase of the output voltage Vₒᵤₜ by driving a separate inductor 122, 124. For example, the switching circuit 110(1) generates a phase of output current as i₁, corresponding to the first phase of the output voltage. Similarly, the switching circuit 110(2) generates the same phase (e.g., the first phase) of output current as i₂. Each switching circuit 110 (e.g., 110(1), 110(2), etc.) includes a driver and a plurality of switches that respond to a signal that the controller 102 provides. The signals that the controller 102 provides to the 110(1) and 110(2) need to be in the same phase, or the 110(1) and 110(2) can share the same signal from the controller 102. The driver controls the operation of each switch in the plurality of switches in accordance with control signals, such as a pulse width modulation (PWM) control signal generated by the controller 102. In various embodiments, the SMPS circuit 100 includes additional phases and/or additional inductor pairs 120. For example, the SMPS circuit 100 can include an additional inductor pair and additional sets of switching circuits 110 (e.g., 110(3), 110(4), etc.) that provide additional phases to the load.

When a switch that is coupling an inductor 122, 124 to the input voltage Vᵢₙ is turned ON, or closed, the switching circuit 110 is coupled to the input voltage Vᵢₙ such that the switching circuit 110 causes the inductor 122, 124 to generate the output voltage Vₒᵤₜ. When the switch is turned OFF, or is open, the switching circuit 110 is disconnected from the input voltage Vᵢₙ and the voltage is not generated by the inductor 122, 124. When the other switch is turned ON, the switching circuit 110 is coupled to ground, and when turned OFF, the switching circuit 110 is disconnected from ground. In the illustrated example of FIG. 1, each switching circuit 110 includes two switches and one driver. However, in some embodiments, each switching circuit 110 includes a different number of switches and/or drivers.

The controller 102 generates one or more control signals for controlling operation of the switching circuits 110. In some embodiments, the controller 102 generates the control signal based on measurements indicative of and/or associated with voltages and/or currents flowing through the SMPS circuit 100. For example, the controller 102 can generate one or more PWM signals based on measurements indicative of and/or associated with currents flowing through the SMPS circuit 100. In operation, the controller 102 applies the one or more control signals to the drivers included in the switching circuits 110 to control the frequency and/or the duty cycle at which the switches included in the switching circuits 110 are turned ON and OFF. The controller 102 can be implemented as any suitable control device and/or circuit for controlling operation of switching circuits 110. For example, the controller 102 can be implemented as one or more of an analog control circuit, a digital control circuit, a microprocessor, an integrated circuit, and/or any other suitable control device for controlling operation of the switching circuits 110. As another example, the controller 102 controls PWM signals based on the output voltage and/or the output current.

Each inductor 122, 124 included in the inductor pair 120 coupled to the output of a respective switching circuit 110 such that the phase current i generated by the respective switching circuit 110 flows through the inductor 122, 124 to provide the output voltage. In some embodiments, each inductor 122, 124 have matching characteristics. For example, the inductor 122 can have an inductance that matches the inductance of the inductor 124. Additionally or alternatively, the inductors 122, 124 can have corresponding core types, number of turns in the inductor coil, coil types, coil shapes, and so forth. In some embodiments, the core of the inductors 122, 124 is an air core, a rod-like core, or a drum-like core. Other shapes for the core of the inductor 122, 124 are possible. For example, the core of the inductor 122, 124 can be a toroid, a block, etc. Additionally or alternatively, the inductor 122, 124 can include a coil around the core. In such instances, the coil shape can differ from the shape of the core.

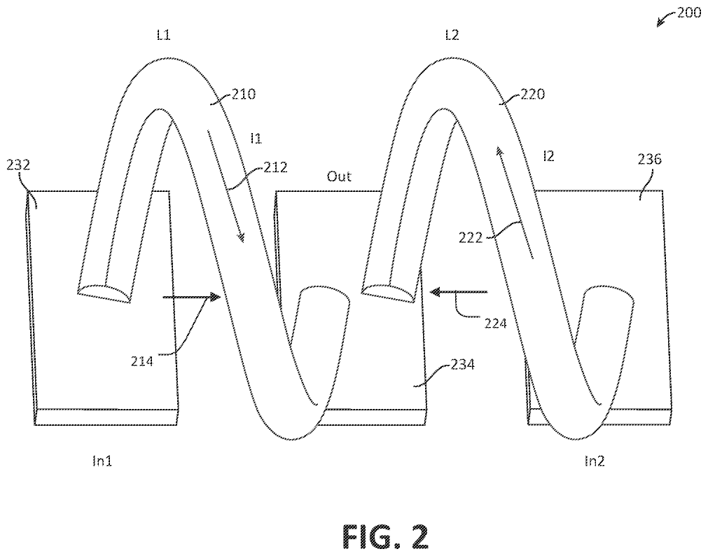

As will be discussed in further detail in relation FIGS. 2-4, the inductors 122, 124 can be physically arranged to reduce magnetic flux that leaks from the inductors 122, 124. For example, the inductor 122 produces a first magnetic field in a first direction, while the inductor 124 produces a second magnetic field in a second direction that is substantially opposite that of the first direction. In such instances, the magnetic flux at locations proximate to the inductor pair 120 is lowered, as the magnetic fields produced by the respective at least partially cancel out.

FIG. 2 illustrates an exemplar pair of cylindrical coil inductors 210, 220 arranged to produce cancelling magnetic fields, according to various embodiments. As shown, the physical arrangement 200 includes, without limitation, a first cylindrical coil inductor (L1) 210, a second cylindrical coil inductor (L2) 220, a first input pad (In1) 232, an output pad (Out) 234, and a second input pad (In2) 236.

In various embodiments, an inductor package includes multiple inductors in a physical arrangement 200 to connect the inductors 210, 220 to other electronic components. For example, the physical arrangement 200 can be included in a single 2-in-1 inductor package that separately connects the inductors 210, 220 to separate electronic components. In such instances, the switching circuit 110(1) can connect to the first inductor 210 via the first input pad 232, the switching circuit 110(2) can connect to the second cylindrical coil inductor 220 via the second input pad 236, and the capacitor 130 can connect to the output pad 234.

In operation, the controller drives the switching circuits 110(1), 110(2) to connect the input voltage to the respective inductors 210, 220. When current flows through a given inductor 210, 220, the current flow generates a magnetic flux, creating a leakage magnetic flux that emanates from the inductor 210, 220. When the inductors 210, 220 carry the same current, due to the physical arrangement 200, the inductor fields perform active magnetic field cancellation, lowering or cancelling the magnetic flux emanating from inductors 210, 220.

For example, when the first inductor 210 is connected to the input voltage, a first current 212 flows through the coil of the first inductor 210. The current 212 in the first inductor 210 generates a magnetic field around portions of the coil. Due to the shape of the coil, the respective magnetic fields at different portions of the coil combine to generate a first magnetic field 214 in the rightward direction, as indicated by the arrow. Similarly, when the second cylindrical coil inductor 220 is connected to the input voltage, a second current 222 flows through the coil of the second inductor 210. The current 222 in the second cylindrical coil inductor 220 generates a magnetic field around portions of the coil. Due to the shape of the coil, the respective magnetic fields at different portions of the coil combine to generate a second magnetic field 224 in the leftward direction, as indicated by the arrow.

In various embodiments, the first inductor 210 and the second cylindrical coil inductor 220 have matching physical characteristics (e.g., same coil material, same core type, same number of turns, matching inductances, etc.). In such instances the first inductor 210 and the second cylindrical coil inductor 220 each produce magnetic fields 214, 224 of equal strength. As shown, the physical arrangement 200 has the first inductor 210 oriented in a first position that is opposite the second position of the second cylindrical coil inductor 220. As a result, the first current 212 flows in the opposite direction of the second current 222. The resulting magnetic fields 214, 224 are in opposite directions, with the second magnetic field 224 counteracting the first magnetic field 214. Consequently, the magnetic flux experienced at locations proximate to the physical arrangement is lowered or cancelled due to the opposing magnetic fields.

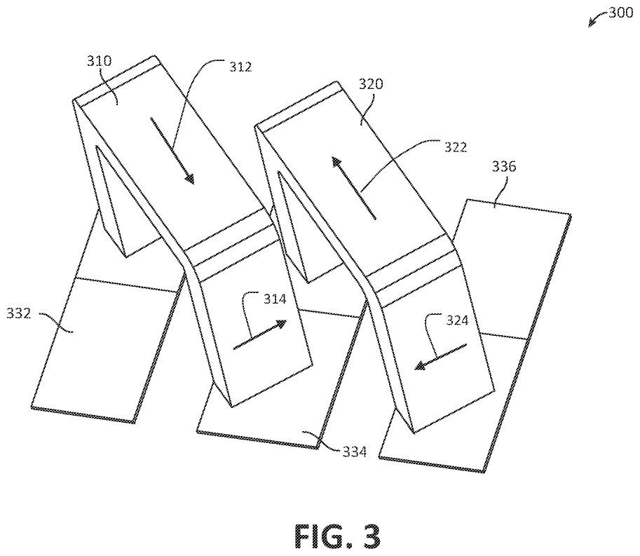

FIG. 3 illustrates an exemplar pair of bridge configuration inductors 310, 320 arranged to produce cancelling magnetic fields, according to various embodiments. As shown, the physical arrangement 300 includes, without limitation, a first bridge configuration inductor 310, a second bridge configuration inductor 320, a first input pad 332, an output pad 334, and a second input pad 336.

The physical arrangement 300 of the first bridge configuration inductor 310 and the second bridge configuration inductor 320 is similar to the physical arrangement 200. In some examples, the first bridge configuration inductor 310 and the second bridge configuration inductor 320 have small inductances and can be used for high-frequency applications.

As shown, the currents 312, 322 flow through the respective first bridge configuration inductor 310 and second bridge configuration inductor 320. The currents 312, 322 generate magnetic fields 314, 324 of matching intensities proximate to the first bridge configuration inductor 310 and the second bridge configuration inductor 320. Due to the physical arrangement 300 and the opposing directions of the currents 312, 322, the magnetic fields 314, 324 perform active magnetic field cancellations and mitigate the intensity of magnetic fluxes proximate to the physical arrangement 300.

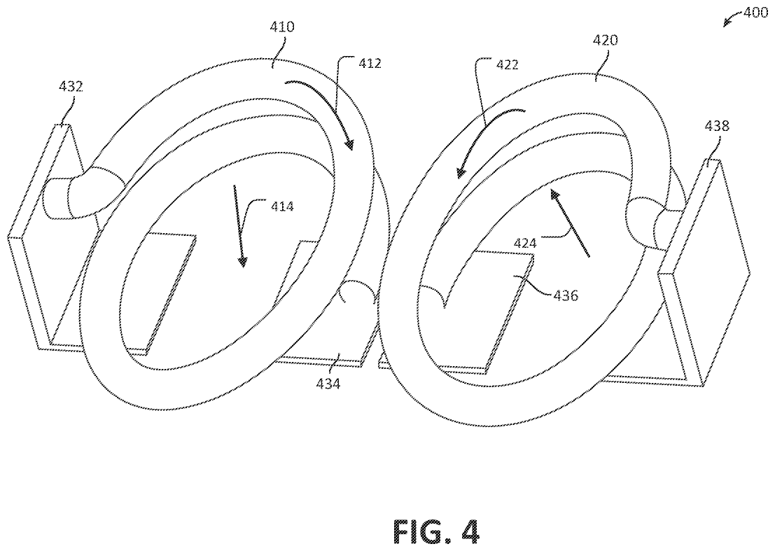

FIG. 4 illustrates an exemplar pair of cylindrical coil inductors 410, 420 arranged in parallel to produce cancelling magnetic fields, according to various embodiments. As shown, the physical arrangement 400 includes, without limitation, a first cylindrical coil inductor 410, a second cylindrical coil inductor 420, a first input pad 432, a first output pad 434, a second output pad 436, and a second input pad 438.

In various embodiments, the physical properties of the first cylindrical coil inductor 410 and the second cylindrical coil inductor 420 are similar to the physical properties of the first cylindrical coil inductor 210 and the second cylindrical coil inductor 220. In some embodiments, the first cylindrical coil inductor 410 and the second cylindrical coil inductor 420 are split and can be included in separate inductor packages. For example, the first cylindrical coil inductor 410 is connected to a first output pad 434 while the second cylindrical coil inductor 420 is connected to a second output pad 436.

As shown, the first cylindrical coil inductor 410 resides parallel to the second cylindrical coil inductor 420. As a result, the first cylindrical coil inductor 410 and the second cylindrical coil inductor 420 produce magnetic fields 414, 424 in opposing directions. Due to the proximity of the first cylindrical coil inductor 410 and the second cylindrical coil inductor 420, the magnetic fields 414, 424 perform active magnetic field cancellation, lowering or cancelling the magnetic flux experienced at locations proximate to the physical arrangement 400.

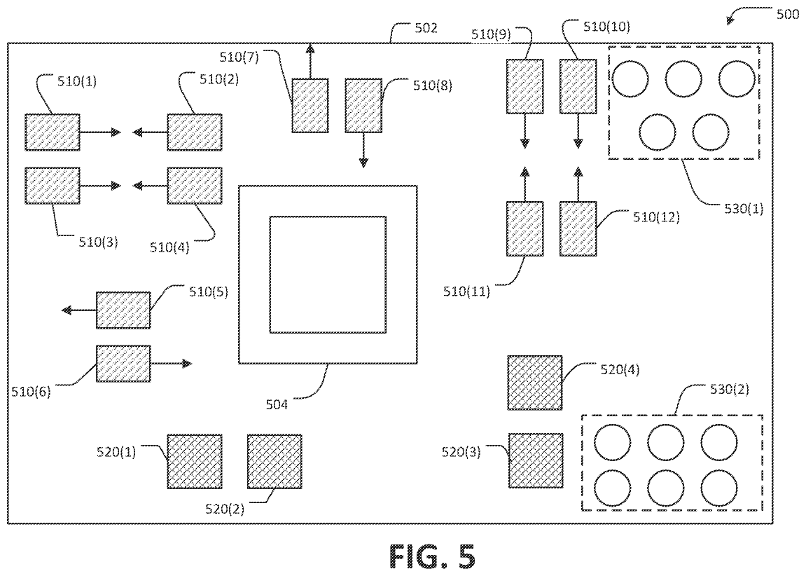

FIG. 5 illustrates a printed circuit board (PCB) assembly 500 that includes one or more inductor packages 510 and one or more 2-in-1 inductor packages 520, according to various embodiments. As shown, and without limitation, the PCB assembly 500 includes a PCB layer 502, a central processing unit (CPU) 504, capacitor banks 530, a set of single inductor packages 510 (e.g., 510(1), 510(2), etc.), and a set of 2-in-1 inductor packages 520.

The PCB assembly 500 is designed to connect a large quantity of electronic components to perform various tasks. As persons skilled in the art will understand, the disclosed designs can be used with various inductors and/or inductor packages (e.g., the inductor packages 510, 520) and therefore, can be used across a wide variety of applications, including, and without limitation, various types of desktops, laptops, workstations, servers, medical devices, automotive devices, and/or robots.

In various embodiments, the inductor packages 510, 520 occupy a smaller area than conventional inductor packages. Further, can be located proximate to other components, as magnetic flux leakage is mitigated or cancelled due to the arrangement of individual packages (e.g., the physical arrangement of the inductor packages 510(9)-510(12)), or the physical arrangement of inductors within a given inductor package (e.g., the inductor pair 120 included in the 2-in-1 inductor package 520(4). The additional density on the PCB assembly 500 afforded by the inductor packages 510, 520 improves the ability to control power use on the PCB assembly 500.

As shown, the inductors and capacitors of the PCB assembly 500 can be separately connected as separate oscillators, filters, switching power circuits (e.g., boost converters, buck converters, boost/buck converters, inverters, etc.), and so forth. The PCB assembly 500 includes two types of inductor packages 510, 520. In various embodiments, the single inductor packages 510 can be split packages that are paired together and physically arranged to produce magnetic fields in opposite directions (as indicated by the respective arrows). In some embodiments, the inductor packages 510, 520 are unshielded and therefore can occupy a smaller area than similar inductor packages that includes extra layers of shielding. For example, the inductor package 510(5) and the inductor package 510(6) are physically arranged on the PCB board 502 such that any magnetic flux leakage emanating from the inductor in the inductor package 510(5) is counteracted by the magnetic flux leakage emanating from the inductor package 510(6). The PCB assembly 500 contains similar physical arrangements (e.g., the group of inductor packages 510(1)-510(4), etc.).

Similarly, the 2-in-1 inductor packages 520 can include an inductor pair 120 that performs the active magnetic field cancellation. In such instances, the 2-in-1 inductor packages 520 do not produce a signification magnetic flux leakage and do not need to be paired with other inductor packages 510, 520.

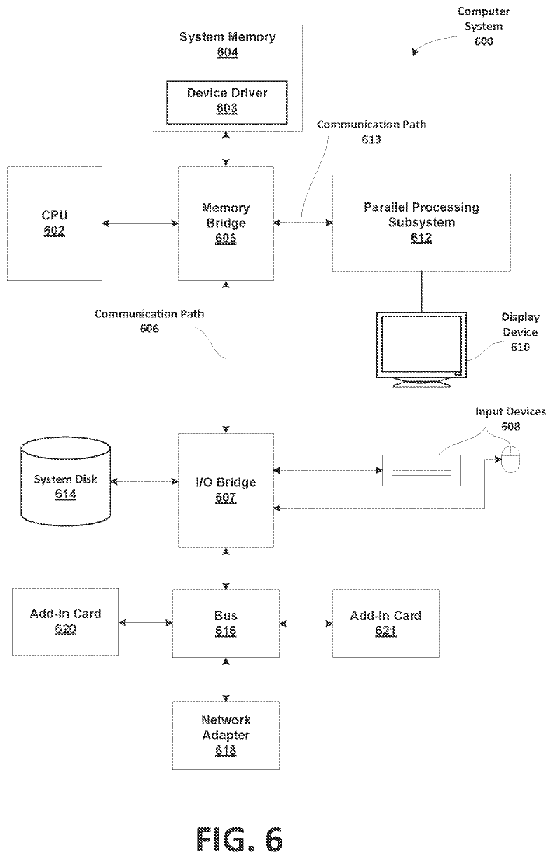

FIG. 6 is a block diagram of a computer system configured to implement one or more aspects of the various embodiments. As shown, computer system 600 includes, without limitation, a central processing unit (CPU) 602 and a system memory 604 coupled to a parallel processing subsystem 612 via a memory bridge 605 and a communication path 613. Memory bridge 605 is further coupled to an I/O (input/output) bridge 607 via a communication path 606, and I/O bridge 607 is, in turn, coupled to a bus 616.

In various embodiments, one or more components of the computer system 600 (e.g., the CPU 602, the parallel processing subsystem 612, etc.) includes one or more circuit boards that incorporate one or more of the shielded inductor packages 510, 520 as part of the circuitry. For example, a circuit board containing the CPU 602 can include one or more switching power circuits that include at least one inductor package 510 and/or at least one 2-in-1 inductor package 520.

In operation, I/O bridge 607 is configured to receive user input information from input devices 608, such as a keyboard or a mouse, and forward the input information to CPU 602 for processing via communication path 606 and memory bridge 605. Bus 616 is configured to provide connections between I/O bridge 607 and other components of the computer system 600, such as a network adapter 618 and various add-in cards 620 and 621.

As also shown, I/O bridge 607 is coupled to a system disk 614 that may be configured to store content and applications and data for use by CPU 602 and parallel processing subsystem 612. As a general matter, system disk 614 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. Finally, although not explicitly shown, other components, such as universal serial bus or other port connections, compact disc drives, digital versatile disc drives, film recording devices, and the like, may be connected to I/O bridge 607 as well.

In various embodiments, memory bridge 605 may be a Northbridge chip, and I/O bridge 607 may be a Southbrige chip. In addition, communication paths 606 and 613, as well as other communication paths within computer system 600, may be implemented using any technically suitable protocols, including, without limitation, AGP (Accelerated Graphics Port), HyperTransport, or any other bus or point-to-point communication protocol known in the art.

In some embodiments, parallel processing subsystem 612 comprises a graphics subsystem that delivers pixels to a display device 610 that may be any conventional cathode ray tube, liquid crystal display, light-emitting diode display, or the like. In such embodiments, the parallel processing subsystem 612 incorporates circuitry optimized for graphics and video processing, including, for example, video output circuitry. As described in greater detail below in FIG. 2, such circuitry may be incorporated across one or more parallel processing units (PPUs) included within parallel processing subsystem 612. In other embodiments, the parallel processing subsystem 612 incorporates circuitry optimized for general purpose and/or compute processing. Again, such circuitry may be incorporated across one or more PPUs included within parallel processing subsystem 612 that are configured to perform such general purpose and/or compute operations. In yet other embodiments, the one or more PPUs included within parallel processing subsystem 612 may be configured to perform graphics processing, general purpose processing, and compute processing operations. System memory 604 includes at least one device driver 603 configured to manage the processing operations of the one or more PPUs within parallel processing subsystem 612. The system memory 604 also includes any number of software applications 625 that execute on the CPU 602 and may issue commands that control the operation of the PPUs.

In various embodiments, parallel processing subsystem 612 may be integrated with one or more other the other elements of FIG. 1 to form a single system. For example, parallel processing subsystem 612 may be integrated with CPU 602 and other connection circuitry on a single chip to form a system on chip (SoC).

It will be appreciated that the system shown herein is illustrative and that variations and modifications are possible. The connection topology, including the number and arrangement of bridges, the number of CPUs 602, and the number of parallel processing subsystems 612, may be modified as desired. For example, in some embodiments, system memory 604 could be connected to CPU 602 directly rather than through memory bridge 605, and other devices would communicate with system memory 604 via memory bridge 605 and CPU 602. In other alternative topologies, parallel processing subsystem 612 may be connected to I/O bridge 607 or directly to CPU 602, rather than to memory bridge 605. In still other embodiments, I/O bridge 607 and memory bridge 605 may be integrated into a single chip instead of existing as one or more discrete devices. Lastly, in certain embodiments, one or more components shown in FIG. 6 may not be present. For example, bus 616 could be eliminated, and network adapter 618 and add-in cards 620, 621 would connect directly to I/O bridge 607.

In sum, a pair of inductors are physically arranged in an inductor package or on a printed circuit board. A first inductor is arranged in a first orientation and produces a first magnetic field in a first direction. A second inductor is arranged in a second oriented and produces a second magnetic field in the second direction that is opposite the first direction. The first inductors and the second inductor are included in a common circuit and connect to an input voltage. A first current flows through the first inductor to generate the first magnetic field. A second current flows through the second inductor to generate the second magnetic field. Due to the physical arrangement of the first inductor and the second inductor, the currents flow through the inductors in opposite directions. The first magnetic field and second magnetic field are generated in opposite directions and perform active magnetic field cancellation. The active magnetic field cancellation causes the magnetic flux experienced at a given location proximate to the pair of inductors to be cancelled or substantially reduced.

At least one technical advantage of the disclosed design relative to the prior art is that, with the disclosed design, a printed circuit board assembly or inductor package includes a complementary pair of inductors that are arranged to limit the magnetic flux that leaks from inductors. In particular, by physically arranging inductors in orientations that produce magnetic fluxes in opposing directions, circuits that use the complementary pair of inductors can drive each inductor in a given inductor pair with large currents without causing a large magnetic flux. Consequently, the disclosed design enables a greater density of inductors to be included in a computer device, such as a printed circuit board, relative to what can be achieved using prior art designs. Further, with the disclosed design, pairs of inductors and inductor packages can be located closer to the other components in a computer device relative to what can be achieved using prior art designs. Accordingly, the disclosed design can improve the ability of a high-performance computing devices to control power use during operation. These technical advantages represent one or more technological improvements over prior art approaches and designs.

1. In various embodiments, an inductor package comprises a first inductor that is arranged in a first orientation and produces a first magnetic flux in a first direction, and a second inductor that is arranged in a second orientation and produces a second magnetic flux in a second direction that at least partially cancels the first magnetic flux, where the first direction is opposite the second direction.

2. The inductor package of clause 1, where a pulse-width modulation signal concurrently drives the first inductor to produce a first current and the second inductor to produce a second current.

3. The inductor package of clause 1 or 2, further comprising an output connection pad that is shared by the first inductor and the second inductor.

4. The inductor package of any of clauses 1-3, where the inductor package is unshielded.

5. The inductor package of any of clauses 1-4, where at least the first inductor or the second inductor comprises a cylindrical coil inductor.

6. The inductor package of any of clauses 1-5, where the first inductor that is arranged in the first orientation resides parallel to the second inductor that is arranged in the second orientation.

7. The inductor package of any of clauses 1-6, where at least the first inductor or the second inductor includes a rod core or a drum core.

8. In various embodiments, a printed circuit board assembly comprises a printed circuit board (PCB) layer, a first inductor that is arranged on the PCB layer at a first orientation and produces a first magnetic flux in a first direction, and a second inductor that is arranged on the PCB layer at a second orientation and produces a second magnetic flux in a second direction that at least partially cancels the first magnetic flux.

9. The printed circuit board assembly of clause 8, where at least the first inductor or the second inductor comprises a cylindrical coil inductor.

10. The printed circuit board assembly of clause 8 or 9, where the first inductor that is arranged in the first orientation resides parallel to the second inductor that is arranged in the second orientation.

11. The printed circuit board assembly of any of clauses 8-10, where at least the first inductor or the second inductor includes a rod core or a drum core.

12. The printed circuit board assembly of any of clauses 8-11, further comprising a first inductor package fixed to the PCB layer that includes the first inductor, and a second inductor package fixed to the PCB layer that includes the second inductor.

13. The printed circuit board assembly of any of clauses 8-12, where both the first inductor and the second inductor are included in an inductor package fixed to the PCB layer.

14. The printed circuit board assembly of any of clauses 8-13, where the inductor package includes an output connection pad that is shared by the first inductor and the second inductor.

15. The printed circuit board assembly of any of clauses 8-14, where the inductor package is unshielded.

16. The printed circuit board assembly of any of clauses 8-15, further comprising a controller that generates a pulse-width modulation signal that concurrently drives the first inductor to produce a first current and the second inductor to produce a second current.

17. The printed circuit board assembly of any of clauses 8-16, further comprising a third inductor that is arranged on the PCB layer at a third orientation and produces a third magnetic flux in a third direction, and a fourth inductor that is arranged on the PCB layer at a fourth orientation and produces a fourth magnetic flux in a fourth direction that at least partially cancels the third magnetic flux.

18. The printed circuit board assembly of any of clauses 8-17, where the controller produces a second pulse-width modulation signal that concurrently drives the third inductor to produce a third current and the fourth inductor to produce a fourth current.

19. The printed circuit board assembly of any of clauses 8-18, where the first inductor and the second inductor are included in a switched mode power supply (SMPS) circuit.

20. The printed circuit board assembly of any of clauses 8-19, where the first inductor and the second inductor are included in one of an oscillator, a filter, a boost converter, or a buck converter.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. An inductor package comprising:
a first inductor that is arranged in a first orientation and produces a first magnetic flux in a first direction; and
a second inductor that is arranged in a second orientation and produces a second magnetic flux in a second direction that at least partially cancels the first magnetic flux,
wherein the first direction is opposite the second direction.

2. The inductor package of claim 1, wherein a pulse-width modulation signal concurrently drives the first inductor to produce a first current and the second inductor to produce a second current.

3. The inductor package of claim 1, further comprising an output connection pad that is shared by the first inductor and the second inductor.

4. The inductor package of claim 1, wherein the inductor package is unshielded.

5. The inductor package of claim 1, wherein at least the first inductor or the second inductor comprises a cylindrical coil inductor.

6. The inductor package of claim 1, wherein the first inductor that is arranged in the first orientation resides parallel to the second inductor that is arranged in the second orientation.

7. The inductor package of claim 1, wherein at least the first inductor or the second inductor includes a rod core or a drum core.

8. A printed circuit board assembly comprising:
a printed circuit board (PCB) layer;
a first inductor that is arranged on the PCB layer at a first orientation and produces a first magnetic flux in a first direction; and
a second inductor that is arranged on the PCB layer at a second orientation and produces a second magnetic flux in a second direction that at least partially cancels the first magnetic flux.

9. The printed circuit board assembly of claim 8, wherein at least the first inductor or the second inductor comprises a cylindrical coil inductor.

10. The printed circuit board assembly of claim 8, wherein the first inductor that is arranged in the first orientation resides parallel to the second inductor that is arranged in the second orientation.

11. The printed circuit board assembly of claim 8, wherein at least the first inductor or the second inductor includes a rod core or a drum core.

12. The printed circuit board assembly of claim 8, further comprising:
a first inductor package fixed to the PCB layer that includes the first inductor, and
a second inductor package fixed to the PCB layer that includes the second inductor.

13. The printed circuit board assembly of claim 8, wherein both the first inductor and the second inductor are included in an inductor package fixed to the PCB layer.

14. The printed circuit board assembly of claim 13, wherein the inductor package includes an output connection pad that is shared by the first inductor and the second inductor.

15. The printed circuit board assembly of claim 13, wherein the inductor package is unshielded.

16. The printed circuit board assembly of claim 8, further comprising a controller that generates a pulse-width modulation signal that concurrently drives the first inductor to produce a first current and the second inductor to produce a second current.

17. The printed circuit board assembly of claim 16, further comprising:
a third inductor that is arranged on the PCB layer at a third orientation and produces a third magnetic flux in a third direction; and
a fourth inductor that is arranged on the PCB layer at a fourth orientation and produces a fourth magnetic flux in a fourth direction that at least partially cancels the third magnetic flux.

18. The printed circuit board assembly of claim 17, wherein the controller produces a second pulse-width modulation signal that concurrently drives the third inductor to produce a third current and the fourth inductor to produce a fourth current.

19. The printed circuit board assembly of claim 8, wherein the first inductor and the second inductor are included in a switched mode power supply (SMPS) circuit.

20. The printed circuit board assembly of claim 8, wherein the first inductor and the second inductor are included in one of an oscillator, a filter, a boost converter, or a buck converter.
